(19) United States
(12) Patent Application Publication
(10) Pub. No.: US 2026/0198354 A1
(43) Pub. Date: Jul. 9, 2026

(54) BUFFER LAYER FOR GLASS CORE

(71) Applicant: Intel Corporation, Santa Clara, CA (US)

(72) Inventors: Whitney BRYKS, Tempe, AZ (US); Yosef KORNBLUTH, Phoenix, AZ (US); Aaditya Anand CANDADAI, Chandler, AZ (US); Bainye Francoise ANGOUA, Phoenix, AZ (US); Hiroki TANAKA, Gilbert, AZ (US)

(21) Appl. No.: 19/015,417

(22) Filed: Jan. 9, 2025

(51) Int. Cl. H01L 23/498; H01L 23/538

(52) U.S. Cl. CPC H10W 70/69; H10W 70/611; H10W 70/635

(57) ABSTRACT

Embodiments disclosed herein may include an apparatus with a substrate that includes a hole through a thickness of the substrate. In an embodiment, the substrate comprises a glass layer, and the hole has a first width. In an embodiment, the apparatus includes a buffer layer on the substrate, and an opening passes through the buffer layer. In an embodiment, the opening is over the hole. In an embodiment, the opening has a second width that is smaller than the first width. In an embodiment, the apparatus further includes a via in the hole and the opening.

### BACKGROUND

Glass cores for package substrates are an attractive option due to the increased stiffness and planarity that they provide compared to existing organic cores. However, the brittle nature of glass provides several challenges with respect to manufacturing. One issue that is present for glass cores is the polishing process used during the fabrication of through glass vias (TGVs). Typically, the plating process results in the deposition of copper on the top and bottom surfaces of the glass core, and a chemical mechanical polishing (CMP) process is used to remove the overburden. However, this results in a relatively high pressure against the glass core as the metal is pushed directly on the glass surface. The high pressure induces stress into the glass core, and the stress can result in cracking and/or other damage to the glass core.

### BRIEF DESCRIPTION OF THE DRAWINGS

FIG. 1A is a cross-sectional illustration of a glass core with buffer layers that includes a via through the buffer layers and the glass core, in accordance with an embodiment.

FIG. 1B is a cross-sectional illustration of a glass core with buffer layers that continue into a via opening and a via through the buffer layers and the glass core, in accordance with an embodiment.

FIGS. 2A-2G are cross-sectional illustrations that depict a process for forming a via through a glass core and overlying buffer layers, in accordance with an embodiment.

FIG. 2H is a flow diagram that describes a process for forming a via through a glass core and overlying buffer layers, in accordance with an embodiment.

FIGS. 3A-3F are cross-sectional illustrations that depict a process for forming a via through a glass core and overlying buffer layers, in accordance with an additional embodiment.

FIG. 3G is a flow diagram that described a process for forming a via through a glass core and overlying buffer layers, in accordance with an additional embodiment.

FIG. 4 is a cross-sectional illustration of an electronic system with a package substrate that comprises a glass core with buffer layers for improved manufacture of through glass vias, in accordance with an embodiment.

FIG. 5 is a schematic of a computing device built in accordance with an embodiment.

### EMBODIMENTS OF THE PRESENT DISCLOSURE

Described herein are electronic systems with glass cores that include buffer layers for through glass via (TGV) fabrication improvement, in accordance with various embodiments. In the following description, various aspects of the illustrative implementations will be described using terms commonly employed by those skilled in the art to convey the substance of their work to others skilled in the art. However, it will be apparent to those skilled in the art that the present disclosure may be practiced with only some of the described aspects. For purposes of explanation, specific numbers, materials and configurations are set forth in order to provide a thorough understanding of the illustrative implementations. However, it will be apparent to one skilled in the art that the present disclosure may be practiced without the specific details. In other instances, well-known features are omitted or simplified in order not to obscure the illustrative implementations.

Various operations will be described as multiple discrete operations, in turn, in a manner that is most helpful in understanding the present disclosure, however, the order of description should not be construed to imply that these operations are necessarily order dependent. In particular, these operations need not be performed in the order of presentation.

Various embodiments or aspects of the disclosure are described herein. In some implementations, the different embodiments are practiced separately. However, embodiments are not limited to embodiments being practiced in isolation. For example, two or more different embodiments can be combined together in order to be practiced as a single device, process, structure, or the like. The entirety of various embodiments can be combined together in some instances. In other instances, portions of a first embodiment can be combined with portions of one or more different embodiments. For example, a portion of a first embodiment can be combined with a portion of a second embodiment, or a portion of a first embodiment can be combined with a portion of a second embodiment and a portion of a third embodiment.

As noted above, existing glass cores provide stiffness and/or improved planarity compared to organic cores. However, the brittle nature of the glass substrate leads to problems during the manufacture of through glass vias (TGVs). Particularly, the plating process for the formation of the TGVs results in the blanket deposition of copper within via openings as well as over the top and bottom surface of the glass core. In order to remove the overburden copper on the top and bottom surfaces, a planarization process (e.g., a chemical mechanical polishing (CMP) process) is used. Such a process compresses the overburden copper directly against the brittle glass core substrate. This can lead to high stresses, and ultimately, cracking or other damage. Other solutions to remove the copper overburden (e.g., chemical etching) may result in uneven recesses in the surfaces of the TGVs. This can lead to stress concentration sites and glass cracking when under thermomechanical cycles and/or bending loads.

Accordingly, embodiments disclosed herein include the formation of a buffer layer over the top and bottom surfaces of the glass core. The buffer layers are provided over the top and bottom surfaces of the glass core before the plating process used to form the TGVs. As such, the overburden copper is deposited on the buffer layers instead of directly on the glass core. That is, a buffer layer separates the copper overburden from the glass core. In an embodiment, the buffer layer is a low modulus material (e.g., an organic buildup film, a polymeric material, such as a polyimide, an epoxy, a benzocyclobutene (BCB), or the like). Accordingly, the buffer layer provides a cushion between the copper overburden and the glass core during polishing. This allows for stress to be distributed more evenly and prevents high stress conditions that may otherwise lead to cracking of the glass core during the manufacture of the TGVs.

In an embodiment, the buffer layer may be applied with any suitable process. For example, the buffer layer may be applied with a slit coating process, a lamination process, or the like. The buffer layer may be “tented” across the via openings that are formed through the glass core. After the layer is formed openings through the buffer layer may be formed with a laser ablation process, a dry etching process, or the like. Other embodiments may include the use of pressure differentials (e.g., sufficient application of a vacuum) to collapse the tented portion of the buffer layer in order to form the opening through the buffer layer. In such an embodiment, the a portion of the buffer layer may cover an upper region (i.e., an upper lip) of the via opening.

After the buffer layer has been formed over and under the glass core, a seed layer may be applied over the sidewalls of the via opening, the sidewalls of the buffer layer opening, and the exposed surfaces of the buffer layer. That is, a substantially continuous seed layer across the interface between the glass core and the buffer layers may be present. An electrolytic plating process can then be used in order to plate up the TGVs within the via openings and within the openings of the buffer layers. Overburden may also deposit on the exposed surfaces of the buffer layers. A subsequent polishing process may be used to remove the overburden. Since the buffer layers are a lower modulus material, the polishing process induces relatively low stresses in the glass core, and the risk of cracking or other damage is significantly reduced.

In yet another embodiment, a removable mask layer may be deposited over the blanket seed layer before the TGV is plated. For example, a resist layer may be provided over the buffer layer in order to prevent overburden from plating up on the top and bottom surfaces. As such, the TGVs may only plate within the via openings. As such, the need for polishing can be reduced.

In some embodiments the polishing process may also be reduced and/or eliminated since the buffer layers can be trimmed with a fly-cutting operation. In such an embodiment, a portion of the buffer layer and the overlying copper overburden may be remove with a fly-cut process. This may also leave TGVs with top surfaces that are substantially coplanar with the top surface of the buffer layer, which can further reduce stresses.

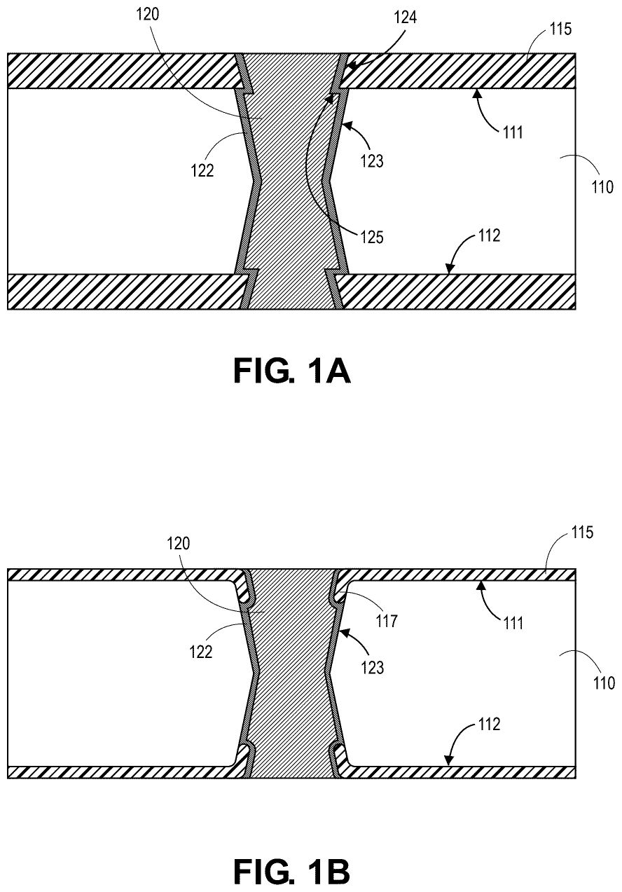

Referring now to FIG. 1A, a cross-sectional illustration of a portion of a glass core 110 is shown, in accordance with an embodiment. In an embodiment, the glass core 110 may be a solid glass layer. In an embodiment, the glass core 110 may be substantially all glass. The glass core 110 may be a solid mass comprising a glass material with an amorphous crystal structure where the solid glass core may also include various structures—such as vias, cavities, channels, or other features—that are filled with one or more other materials (e.g., metals, metal alloys, dielectric materials, etc.). As such, glass core 110 may be distinguished from, for example, the “prepreg” or “FR4” core of a Printed Circuit Board (PCB) substrate which typically comprises glass fibers embedded in a resinous organic material, such as an epoxy.

The glass core 110 may have any suitable dimensions. In a particular embodiment, the glass core 110 may have a thickness that is approximately 50 μm or greater. For example, the thickness of the glass core 110 may be between approximately 50 μm and approximately 1.4 mm. Though, smaller or larger thicknesses may also be used. The glass core 110 may have edge dimensions (e.g., length, width, etc.) that are approximately 10 mm or greater. For example, edge dimensions may be between approximately 10 mm to approximately 250 mm. Though, larger or smaller edge dimensions may also be used. More generally, the area dimensions of the glass core 110 (from an overhead plan view) may be between approximately 10 mm×10 mm and approximately 250 mm×250 mm. In an embodiment, the glass core 110 may have a first side that is perpendicular or orthogonal to a second side. In a more general embodiment, the glass core 110 may comprise a rectangular prism volume with sections (e.g., vias) removed and filled with other materials (e.g., metal, etc.).

The glass core 110 may comprise a single monolithic layer of glass. In other embodiments, the glass core 110 may comprise two or more discrete layers of glass that are stacked over each other. The discrete layers of glass may be provided in direct contact with each other, or the discrete layers of glass may be mechanically coupled to each other by an adhesive or the like. The discrete layers of glass in the glass core 110 may each have a thickness less than approximately 50 μm. For example, discrete layers of glass in the glass core 110 may have thicknesses between approximately 25 μm and approximately 50 μm. Though, discrete layers of glass may have larger or smaller thicknesses in some embodiments. As used herein, “approximately” may refer to a range of values within ten percent of the stated value. For example approximately 50 μm may refer to a range between 45 μm and 55 μm.

The glass core 110 may be any suitable glass formulation that has the necessary mechanical robustness and compatibility with semiconductor packaging manufacturing and assembly processes. For example, the glass core 110 may comprise aluminosilicate glass, borosilicate glass, alumino-borosilicate glass, silica, fused silica, or the like. In some embodiments, the glass core 110 may include one or more additives, such as, but not limited to, Al₂O₃, B₂O₃, MgO, CaO, SrO, BaO, SnO₂, Na₂O, K₂O, SrO, P₂O₃, ZrO₂, Li₂O, Ti, or Zn. More generally, the glass core 110 may comprise silicon and oxygen, as well as any one or more of aluminum, boron, magnesium, calcium, barium, tin, sodium, potassium, strontium, phosphorus, zirconium, lithium, titanium, or zinc. In an embodiment, the glass core 110 may comprise at least 23 percent silicon (by weight) and at least 26 percent oxygen (by weight). In some embodiments, the glass core 110 may further comprise at least 5 percent aluminum (by weight).

In an embodiment, a buffer layer 115 may be provided over a top surface 111 and/or a bottom surface 112 of the glass core 110. The buffer layer 115 may comprise a material that has a modulus that is lower than a modulus of the glass core 110. The buffer layer 115 may be an organic dielectric material, such as a buildup film or the like. Though, the buffer layer 115 may comprise any suitable polymeric material, such as a polyimide, an epoxy, a BCB, or the like.

In an embodiment, a TGV 120 may pass through a thickness of the glass core 110. The TGV 120 may also pass through the thickness of the buffer layers 115 over and/or under the glass core 110. In an embodiment, the TGV 120 may have a cross-sectional profile that is defined by sidewalls of a via opening that passes through the glass core 110 and the buffer layers 115. In an embodiment, sidewalls 123 of a via opening through the glass core 110 may have an hourglass shaped profile. Though, it is to be appreciated that the slope of the sidewalls 123 through the glass core 110 may include a single taper or substantially no taper in some embodiments. In an embodiment, the sidewalls 124 of the via opening through the buffer layers 115 may also have a slope. In some embodiments, the slope of the sidewalls 124 may be different than a slope of the sidewalls 123.

Further, a step 125 may be present at the interface between the glass core 110 and the buffer layers 115. The step 125 may be the result of the buffer layers 115 overhanging an edge of the via opening through the glass core 110, as will be described in greater detail during the description of the process flow. In some embodiments, a width of the TGV 120 proximate to a bottom of the buffer layer 115 is narrower than a width of the TGV 120 proximate to a top of the glass core 110.

As shown, the TGV 120 may be spaced away from the glass core 110 and the buffer layers 115 by a seed layer 122. In an embodiment, the seed layer 122 may conform to the sidewalls of the via openings through the glass core 110 and the buffer layers 115. That is, the seed layer 122 may conform to the sidewalls 123 and 124. Due to the overhang at the step 125, the seed layer 122 may also have a horizontal portion that covers a surface of the buffer layers 115 that faces towards the glass core 110. Further, it is to be appreciated that the seed layer 122 may not deposit on the top and/or bottom surfaces of the glass core 110. Stated differently, the buffer layers 115 directly contact the top and/or bottom surfaces of the glass core 110. As such, there is no overburden copper that plates directly up from the top and/or bottom surfaces of the glass core 110.

In an embodiment, the TGV 120 may comprise substantially copper or an alloy that comprises copper. The seed layer 122 may comprise any suitable seed layer material, such as titanium, copper, ruthenium, or the like. In some embodiments, the seed layer 122 may be a thin layer. For example, the seed layer may not be discernible or distinguishable from the TGV 120 in some instances. Further, the seed layer 122 may not be a continuous layer. That is, in some locations a portion of the TGV 120 may directly contact the buffer layer 115 and/or the glass core 110.

Referring now to FIG. 1B, a cross-sectional illustration of a glass core 110 is shown, in accordance with an additional embodiment. In an embodiment, the glass core 110 in FIG. 1B is similar to the glass core 110 in FIG. 1A, with the exception of the buffer layer 115. Instead of having a buffer layer 115 that remains outside of the via opening within the glass core 110, the buffer layer 115 in FIG. 1B extends into outer regions of the via opening within the glass core 110. For example, a portion 117 of the buffer layer 115 may cover a rim (i.e., a lip) of the via opening at the top and/or bottom of the glass core 110. Such an intrusion of the buffer layer 115 into the via opening may be formed due to the manufacturing process used to generate the hole through the buffer layer 115. For example, a pressure differential may pull a tented portion of the buffer layer 115 down into the via opening. The tenting process and subsequent formation of openings in the buffer layer will be described in greater detail below.

As shown, the seed layer 122 may conform to the portion 117 of the buffer layer 115 that intrudes into the via opening of the glass core 110. Accordingly, the entire sidewall 123 of the via opening may not be covered by the seed layer 122 since the portion 117 of the buffer layer 115 may separate the seed layer 122 from the glass core 110 at the upper and/or lower ends of the via opening. Similar to the embodiment shown in FIG. 1A, the buffer layer 115 is in direct contact with the top and/or bottom surfaces of the glass core 110. As such, overburden copper is not plated up over and/or under the glass core 110.

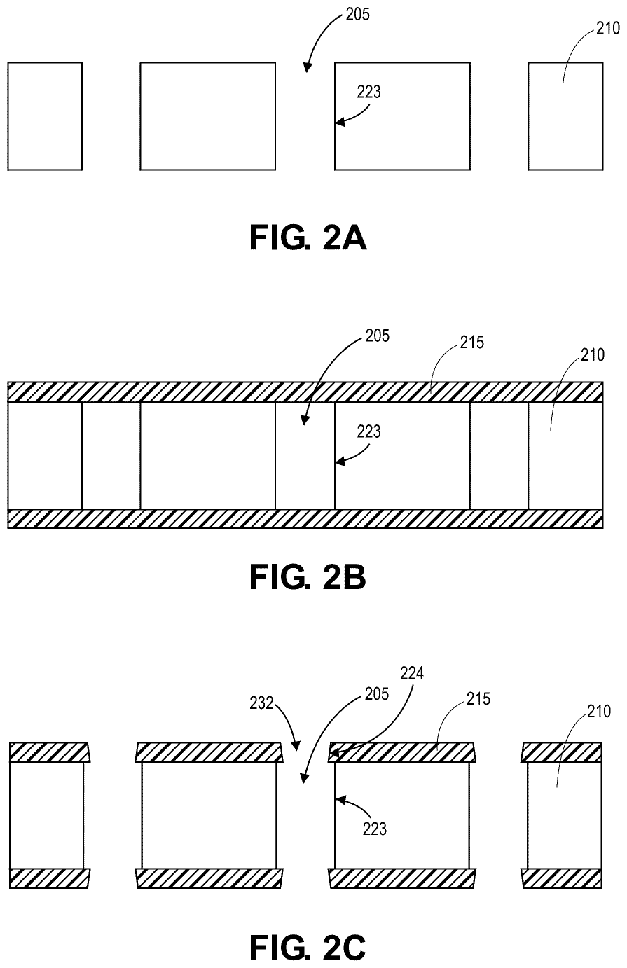

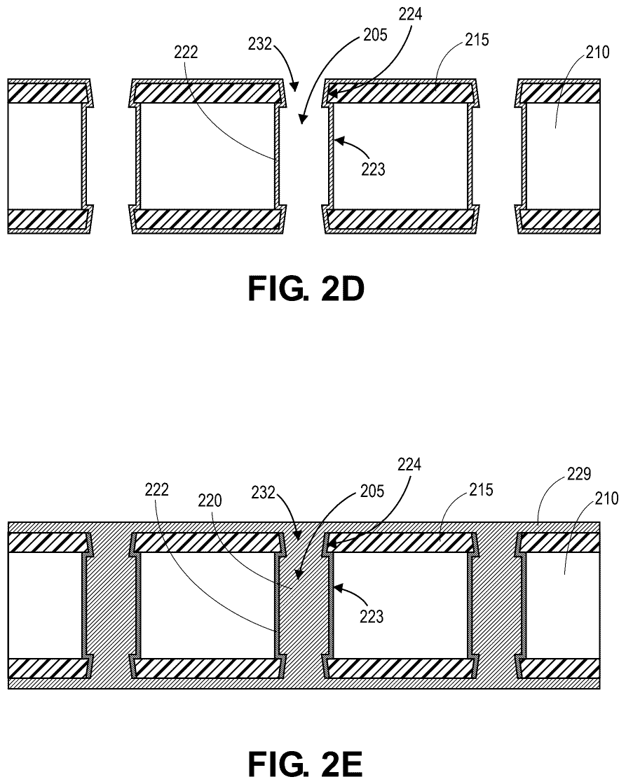

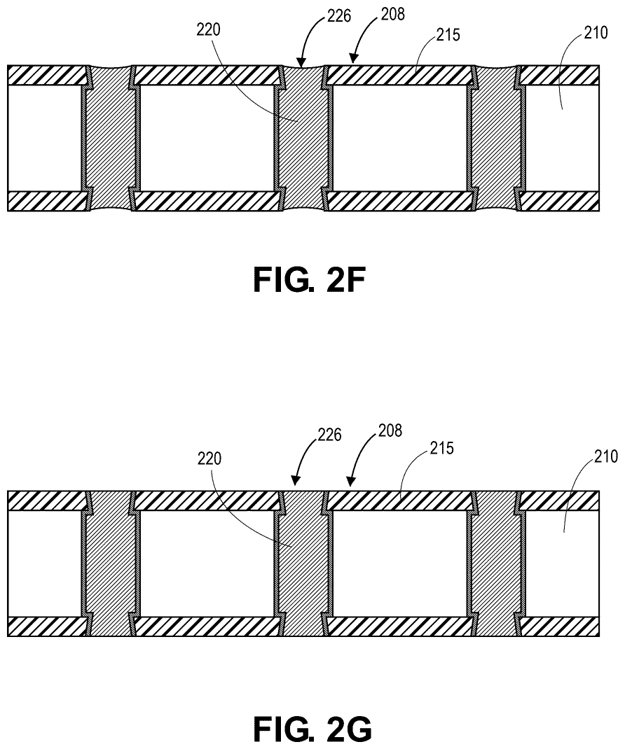

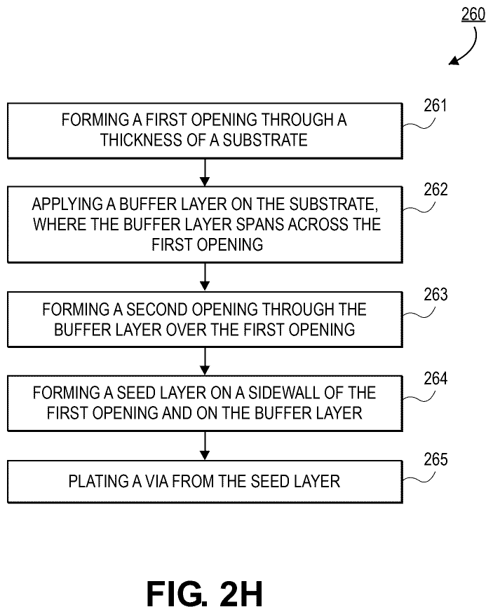

Referring now to FIGS. 2A-2G, a series of cross-sectional illustrations depicting a process for forming a glass core 210 with TGVs 220 is shown, in accordance with an embodiment. In the embodiments shown in FIGS. 2A-2G, overburden copper that is formed during the plating of the TGVs is separated from the glass core 210 by a buffer layer 215. As such, subsequent polishing operations generate less stress on the glass core 210 and minimize cracking and/or other damage.

Referring now to FIG. 2A, a cross-sectional illustration of a portion of a glass core 210 is shown, in accordance with an embodiment. In an embodiment, the glass core 210 may be similar to any of the glass cores described in greater detail herein. In an embodiment, via openings 205 (which may sometimes be referred to as a “hole” or a “via hole”) may be formed through a thickness of the glass core 210. The via openings 205 may be formed with any suitable subtractive patterning process. In a particular embodiment, a laser assisted etching process may be used to form the via openings 205. The cross-sectional profile of the via openings 205 may be dependent on the process used to form the via openings 205. In FIG. 2A, the via openings 205 are shown as having sidewalls 223 that are substantially vertical. Though, the sidewalls 223 may be tapered, sloped, curved, or have any other profile in different embodiments.

Referring now to FIG. 2B, a cross-sectional illustration of the portion of the glass core 210 after buffer layers 215 are provided over the glass core 210 is shown, in accordance with an embodiment. In an embodiment, the buffer layers 215 may be provided on the top and/or bottom surfaces of the glass core 210. In an embodiment, the buffer layers 215 span across the via openings 205. That is, the buffer layers 215 may “tent” across the via openings 205 as opposed to filling the via openings 205. The buffer layers 215 may be applied with any suitable deposition process. In one embodiment, the buffer layers 215 are applied with a slit coating process. For example, the buffer layers 215 may be applied as a liquid coating and cured to form a polymeric layer on the glass core 210. In other embodiments, the buffer layers 215 are applied with a lamination process. In an embodiment, the buffer layers 215 may comprise any suitable low modulus material, such as an organic buildup film or any of the other polymers described in greater detail herein.

Referring now to FIG. 2C, a cross-sectional illustration of the glass core 210 after openings 232 are formed through the buffer layers 215 is shown, in accordance with an embodiment. In an embodiment, the openings 232 may be formed with any suitable process. In one embodiment, a laser ablation process or a dry etching process is used to produce the openings 232. In such an embodiment, a portion of the buffer layer 215 may overhang the edge of the via openings 205 through the glass core 210. That is, the openings 232 in the buffer layers 215 may be narrower than the via openings 205. In an embodiment, a slope of the sidewall 224 of the openings 232 may be different than a slope of the sidewall 223 of the via opening 205.

In an alternative embodiment, the openings 232 in the buffer layers 215 may be formed through a pressure differential process. For example, a pressure differential may collapse the tented portions of the buffer layer 215 across the via openings 205. Such an embodiment may result in portions of the buffer layer 215 intruding into the via opening 205 and covering an upper edge of the sidewalls 223 (e.g., similar to the embodiment shown in FIG. 1B).

Referring now to FIG. 2D, a cross-sectional illustration of the glass core 210 after a seed layer 222 is applied is shown, in accordance with an embodiment. In an embodiment, the seed layer 222 may be applied with any suitable process (e.g., an electroless process, atomic layer deposition, physical vapor deposition, etc.). As shown, the seed layer 222 is deposited along the sidewalls 223 of the via opening 205, the sidewalls 224 of the openings 232, and the exposed surfaces (top surface and bottom surface) of the buffer layers 215. That is, the buffer layers 215 are provided between the seed layer 222 and the top and/or bottom surfaces of the glass core 210.

Referring now to FIG. 2E, a cross-sectional illustration of the glass core 210 after a plating process is used to form the TGVs 220 is shown, in accordance with an embodiment. In an embodiment, the plating process may be an electrolytic plating process that plates copper up from the seed layer 222. As such, the via openings 205 and the openings 232 may be filled with the TGVs 220. Additionally, overburden 229 may plate up from above and/or below the buffer layers 215.

Referring now to FIG. 2F, a cross-sectional illustration of the glass core 210 after a polishing process to remove the overburden 229 is shown, in accordance with an embodiment. In an embodiment, the overburden 229 may be removed with a polishing process (e.g., a CMP process). Since the buffer layer 215 is provided between the overburden 229 and the glass core 210, the pressure from the polishing process is more evenly distributed and damage to the glass core 210 is mitigated. The polishing process may also remove portions of the seed layer 222 over the top and bottom surfaces of the buffer layer 215.

As shown in FIG. 2F, the polishing process may result in the top surface 226 of the TGVs 220 being recessed with respect to the top surface 208 of the buffer layer 215. Though, in some embodiments, the recessing may be mitigated through control of various polishing conditions and/or parameters. However, a more planar top surface may be provided through the use of a fly-cutting process shown in FIG. 2G. Instead of a polishing process, the buffer layer 215 may provide a sufficient margin to allow for a fly-cut to trim the overburden 229 and a portion of the buffer layer 215. In such an embodiment, the top surface 226 of the TGV 220 may be substantially coplanar with the top surface 208 of the buffer layer 215.

Referring now to FIG. 2H, a flow diagram depicting a process 260 for forming a glass core with TGVs is shown, in accordance with an embodiment. In an embodiment, the process 260 may be similar to the process described above with respect to FIGS. 2A-2G.

In an embodiment, the process 260 may begin with operation 261, which comprises forming a first opening through a thickness of a substrate. The substrate may be a glass core. In an embodiment, the first opening may be formed with a laser assisted patterning process or any other suitable substrative patterning process.

In an embodiment, the process 260 may continue with operation 262, which comprises applying a buffer layer on the substrate. In an embodiment, the buffer layer spans across the first opening. The buffer layer may be a low modulus material, such as an organic buildup film or any of the other polymers described in greater detail herein. The buffer layer may be applied with a lamination process, a slit coating process, or the like.

In an embodiment, the process 260 may continue with operation 263, which comprises forming a second opening through the buffer layer over the first opening. In an embodiment, the second opening is formed with a laser patterning process, a dry etching process, or through collapsing the buffer layer over the first opening with a pressure differential process.

In an embodiment, the process 260 may continue with operation 264, which comprises forming a seed layer on a sidewall of the first opening and on the buffer layer. In an embodiment, the seed layer may be deposited with any suitable deposition process. Thereafter, process 260 may continue with operation 265, which comprises plating a via from the seed layer. In an embodiment, overburden from the plating process may be removed with a polishing process or through a fly-cutting process. The buffer layer provides a mechanical buffer to prevent damage to the glass core during polishing, and/or the buffer layer provides margin to allow for a fly-cutting operation.

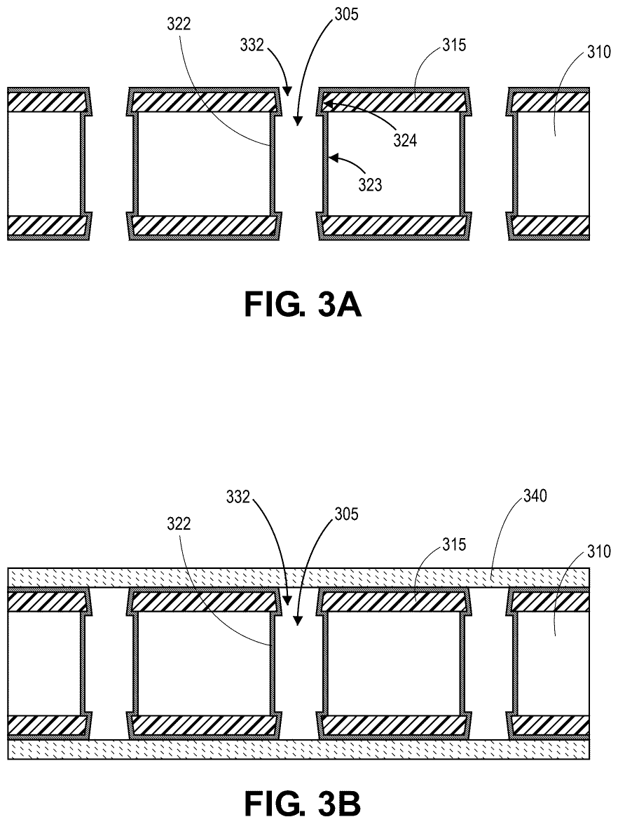

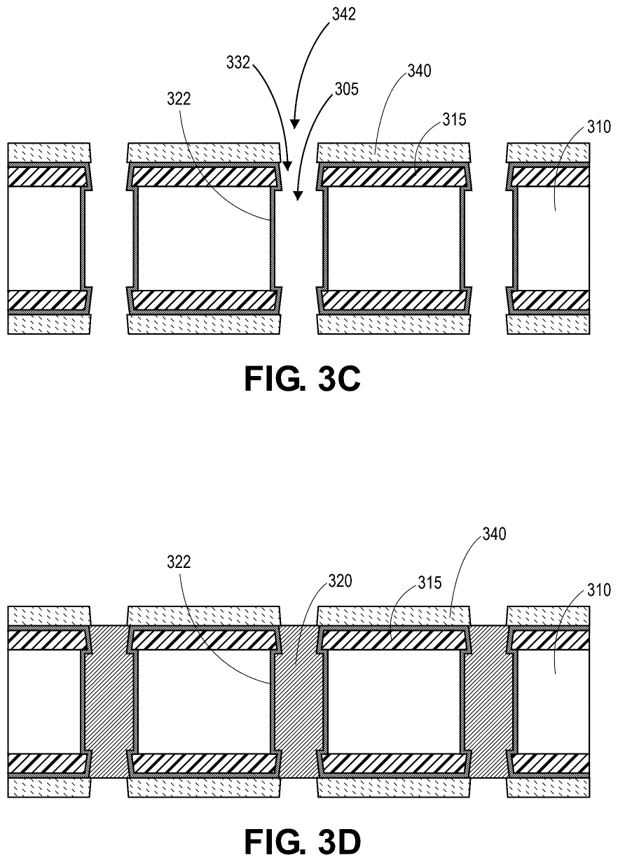

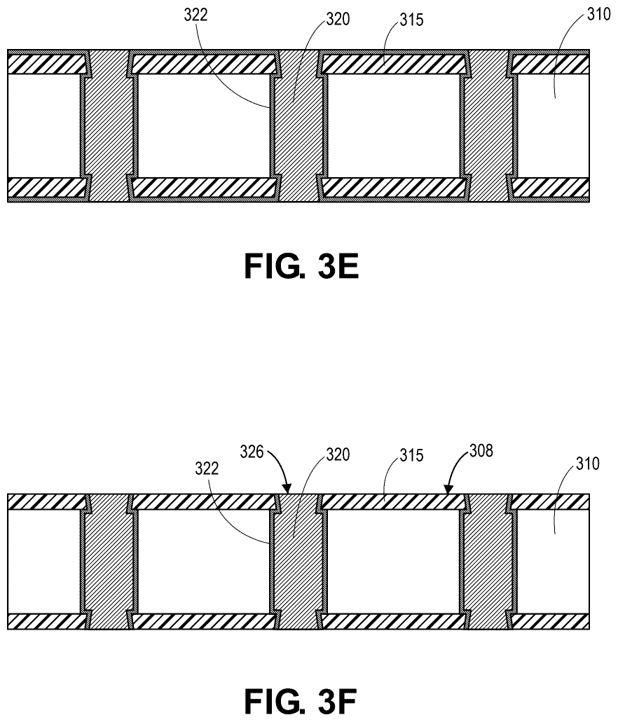

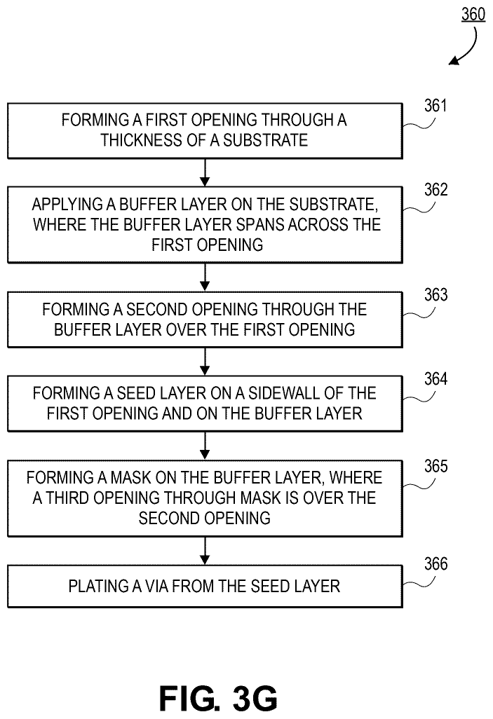

In FIGS. 2A-2H, the TGV formation relies on a polishing and/or fly-cutting process in order to remove the overburden over the top and/or bottom surfaces of the glass core. Alternative embodiments may include the formation of a mask layer over portions of the seed layer outside of the via openings. As such, there does not need to be significant polishing. An example of such a process is shown in FIGS. 3A-3F.

Referring now to FIG. 3A, a cross-sectional illustration of a portion of a glass core 310 is shown, in accordance with an embodiment. In an embodiment, the glass core 310 may be similar to the glass core 210 shown in FIG. 2D. For example, buffer layers 315 may be provided on the glass core 310. Via openings 305 are provided through the glass core 310, and openings 332 are provided through the buffer layers 315. In an embodiment, the seed layer 322 may be provided along sidewalls 323 of the via openings 305 and the sidewalls 324 of the openings through the buffer layers 315. The seed layer 322 may also be over the top and/or bottom surfaces of the buffer layers 315.

Referring now to FIG. 3B, a cross-sectional illustration of the glass core 310 after a temporary layer 340 is applied over the buffer layers 315 is shown, in accordance with an embodiment. In an embodiment, the temporary layer 340 may be a masking layer, such as a resist layer. The temporary layer 340 may be applied with a lamination process, slit coating, or the like. The temporary layer 340 buries the seed layer 322.

Referring now to FIG. 3C, a cross-sectional illustration of the glass core 310 after the temporary layer 340 is patterned to form openings 342 is shown, in accordance with an embodiment. In an embodiment, the openings 342 are formed with a laser ablation process, a dry etching process, a pressure differential process, or the like.

Referring now to FIG. 3D, a cross-sectional illustration of the glass core 310 after the TGVs 320 are plated is shown, in accordance with an embodiment. Since the temporary layer 340 covers the portions of the seed layer 322 over the top and bottom surfaces of the glass core 310, there is no overburden that needs to be removed. That is, the plating is localized to the openings where the TGVs 320 are desired.

Referring now to FIG. 3E, a cross-sectional illustration of the glass core 310 after the temporary layer 340 is removed is shown, in accordance with an embodiment. The temporary layer 340 may be removed with any suitable process, such as an etching process, a stripping process, an ashing process, or the like. The removal of the temporary layer 340 may expose the seed layer 322.

Referring now to FIG. 3F, a cross-sectional illustration of the glass core 310 after the seed layer 322 is removed is shown, in accordance with an embodiment. In an embodiment, the seed layer 322 is removed with an etching process or the like. Though, a polishing process, a fly-cutting process, or any other suitable process may be used as well. In an embodiment, a top surface 326 of the TGV 320 may be substantially coplanar with a top surface 308 of the buffer layer 315.

Referring now to FIG. 3G, a flow diagram depicting a process 360 for forming a glass core with TGVs is shown, in accordance with an embodiment. In an embodiment, the process 360 may be similar to the process described above with respect to FIGS. 3A-3F.

In an embodiment, the process 360 may begin with operation 361, which comprises forming a first opening through a thickness of a substrate. The substrate may be a glass core. In an embodiment, the first opening may be formed with a laser assisted patterning process or any other suitable substrative patterning process.

In an embodiment, the process 360 may continue with operation 362, which comprises applying a buffer layer on the substrate. In an embodiment, the buffer layer spans across the first opening. The buffer layer may be a low modulus material, such as an organic buildup film or any of the other polymers described in greater detail herein. The buffer layer may be applied with a lamination process, a slit coating process, or the like.

In an embodiment, the process 360 may continue with operation 363, which comprises forming a second opening through the buffer layer over the first opening. In an embodiment, the second opening is formed with a laser patterning process, a dry etching process, or through collapsing the buffer layer over the first opening with a pressure differential process.

In an embodiment, the process 360 may continue with operation 364, which comprises forming a seed layer on a sidewall of the first opening and on the buffer layer. In an embodiment, the seed layer may be deposited with any suitable deposition process.

In an embodiment, the process 360 may continue with operation 365, which comprises forming a mask on the buffer layer. In an embodiment, a third opening may be provided through the mask, and the third opening may be over the second opening. The mask may cover portions of the seed layer that are on the top and/or bottom surfaces of the buffer layer.

Thereafter, process 360 may continue with operation 366, which comprises plating a via from the seed layer. In an embodiment, the mask layer may then be removed, and any residual seed layer on the buffer layer can be removed with an etching process or the like.

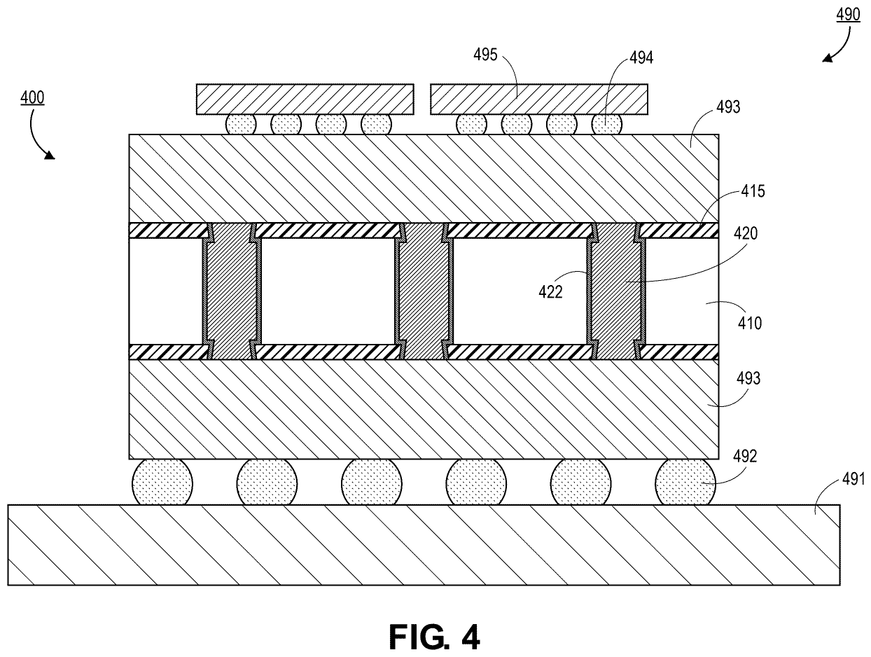

Referring now to FIG. 4, a cross-sectional illustration of an electronic system 490 is shown, in accordance with an embodiment. In an embodiment, the electronic system 490 may comprise a board 491, such as a printed circuit board (PCB), a motherboard, or the like. In an embodiment, the board 491 may be coupled to an electronic package 400 by second level interconnects (SLIs) 492. In an embodiment, the SLIs 492 may comprise solder balls, sockets, or the like.

In an embodiment, the electronic package 400 may comprise a package core 410. In an embodiment, the core 410 may be a glass core 410. In an embodiment, buffer layers 415 may be provided over and/or under the glass core 410. A via 420 that is lined by a continuous seed layer 422 is provided through the buffer layers 415 and the glass core 410. In an embodiment, buildup layers 493 may be provided over the buffer layers 415. Though, in some embodiments, the buildup layers 493 and the buffer layers 415 may be substantially the same material. That is, there may not be a discernable boundary between the buffer layers 415 and the buildup layers 493 of the electronic package 400.

In an embodiment, a die 495 may be coupled to the buildup layers 493 by first level interconnects (FLIs) 494. The FLIs 494 may be any suitable FLI architecture, such as solder balls, copper bumps, or the like. In an embodiment, the one or more dies 495 may be any type of die (e.g., a processor die (e.g., a central processing unit (CPU), a graphics processing unit (GPU), an XPU), a memory die, a communications die, a power management die, and/or the like). In an embodiment, two or more dies 495 may be electrically coupled together by a bridge (not shown) that is embedded in the buildup layers 493 or provided over the buildup layers 493.

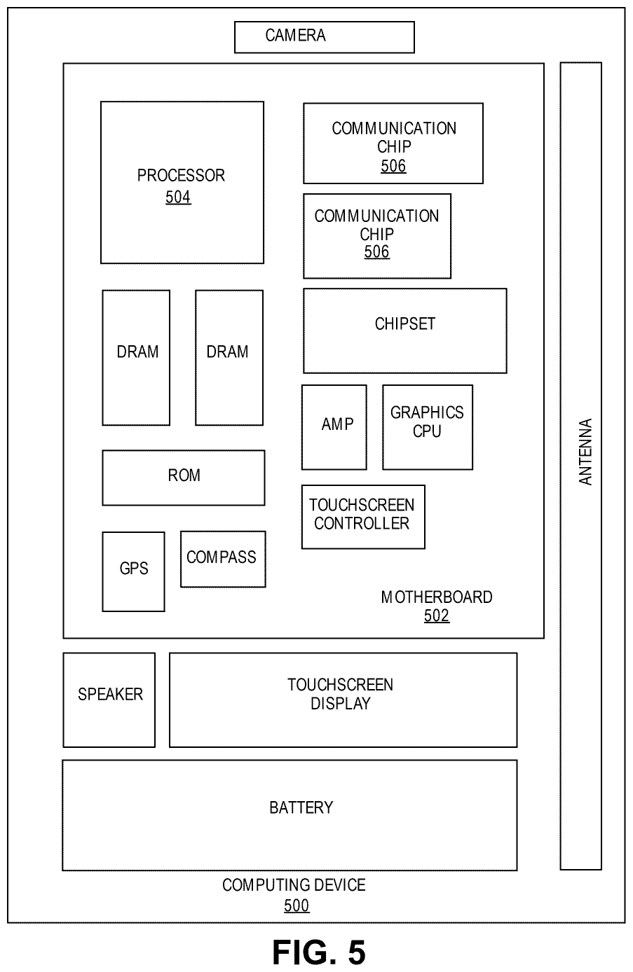

FIG. 5 illustrates a computing device 500 in accordance with one implementation of the disclosure. The computing device 500 houses a board 502. The board 502 may include a number of components, including but not limited to a processor 504 and at least one communication chip 506. The processor 504 is physically and electrically coupled to the board 502. In some implementations the at least one communication chip 506 is also physically and electrically coupled to the board 502. In further implementations, the communication chip 506 is part of the processor 504. In an embodiment, a device package is coupled to the board 502. One or both of the processor 504 or the communication chip 506 may be coupled to the board 502 through the device package.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 506 enables wireless communications for the transfer of data to and from the computing device 500. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 506 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 500 may include a plurality of communication chips 506. For instance, a first communication chip 506 may be dedicated to shorter range wireless communications such as Wi-Fi and Bluetooth and a second communication chip 506 may be dedicated to longer range wireless communications such as GPS, EDGE, GPRS, CDMA, WiMAX, LTE, Ev-DO, and others.

The processor 504 of the computing device 500 includes an integrated circuit die packaged within the processor 504. In some implementations of the disclosure, the integrated circuit die of the processor may be part of a package substrate with a glass core that has a buffer layer and a TGV through the glass core and the buffer layer, in accordance with embodiments described herein. The term “processor” may refer to any device or portion of a device that processes electronic data from registers and/or memory to transform that electronic data into other electronic data that may be stored in registers and/or memory.

The communication chip 506 also includes an integrated circuit die packaged within the communication chip 506. In accordance with another implementation of the disclosure, the integrated circuit die of the communication chip may be part of a package substrate with a glass core that has a buffer layer and a TGV through the glass core and the buffer layer, in accordance with embodiments described herein.

In an embodiment, the computing device 500 may be part of any apparatus. For example, the computing device may be part of a personal computer, a server, a mobile device, a tablet, an automobile, or the like. That is, the computing device 500 is not limited to being used for any particular type of system, and the computing device 500 may be included in any apparatus that may benefit from computing functionality.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

### EXAMPLES

Example 1: an apparatus, comprising: a substrate with a hole through a thickness of the substrate, wherein the substrate comprises a glass layer, and wherein the hole has a first width; a buffer layer on the substrate, wherein an opening passes through the buffer layer, wherein the opening is over the hole, and wherein the opening has a second width that is smaller than the first width; and a via in the hole and the opening.
Example 2: the apparatus of Example 1, wherein the buffer layer comprises a polymer.
Example 3: the apparatus of Example 1 or Example 2, wherein a surface of the via is coplanar with a surface of the buffer layer.
Example 4: the apparatus of Examples 1-3, wherein a surface of the via is recessed from a surface of the buffer layer.
Example 5: the apparatus of Examples 1-4, further comprising: a seed layer, wherein the seed layer lines a sidewall of the hole and a sidewall of the opening.
Example 6: the apparatus of Example 5, wherein the seed layer covers an overhang surface of the buffer layer.
Example 7: the apparatus of Examples 1-6, wherein the buffer layer covers a portion of a sidewall of the hole.
Example 8: the apparatus of Examples 1-7, wherein the substrate is a core of a package substrate.
Example 9: the apparatus of Examples 1-8, wherein the buffer layer is an organic buildup film.
Example 10: the apparatus of Examples 1-9, wherein the hole has an hourglass shaped cross-section.
Example 11: an apparatus, comprising: a glass core; a buffer layer over and in direct contact with the glass core; and a via through the glass core and the buffer layer, wherein the via comprises: a first sidewall with a first slope through the buffer layer; and a second sidewall with a second slope through at least a portion of the glass core, wherein the second slope is different than the first slope.
Example 12: the apparatus of Example 11, wherein the via further comprises: a step between the first sidewall and the second sidewall.
Example 13: the apparatus of Example 11 or Example 12, further comprising: a seed layer, wherein the seed layer is between the via and the glass core, and wherein the seed layer is between the via and the buffer layer.
Example 14: the apparatus of Examples 11-13, wherein the buffer layer comprises an organic buildup film.
Example 15: the apparatus of Examples 11-14, wherein a top surface of the via is coplanar with a top surface of the buffer layer.
Example 16: the apparatus of Examples 11-15, wherein a top surface of the via is recessed from a top surface of the buffer layer.
Example 17: the apparatus of Examples 11-16, further comprising: buildup layers over the buffer layer.
Example 18: an apparatus, comprising: a board; a package substrate coupled to the board, wherein the package substrate comprises: a glass core; a layer over the glass core; and a via through the glass core and the layer, wherein the via is separated from the glass core and the layer by a seed layer; and a die coupled to the package substrate.
Example 19: the apparatus of Example 18, wherein the layer is an organic buildup film, and wherein the layer directly contacts the glass core.
Example 20: the apparatus of Example 18 or Example 19, wherein the via has a stepped profile.

What is claimed is:

1. An apparatus, comprising:
a substrate with a hole through a thickness of the substrate, wherein the substrate comprises a glass layer, and wherein the hole has a first width;
a buffer layer on the substrate, wherein an opening passes through the buffer layer, wherein the opening is over the hole, and wherein the opening has a second width that is smaller than the first width; and
a via in the hole and the opening.

2. The apparatus of claim 1, wherein the buffer layer comprises a polymer.

3. The apparatus of claim 1, wherein a surface of the via is coplanar with a surface of the buffer layer.

4. The apparatus of claim 1, wherein a surface of the via is recessed from a surface of the buffer layer.

5. The apparatus of claim 1, further comprising:
a seed layer, wherein the seed layer lines a sidewall of the hole and a sidewall of the opening.

6. The apparatus of claim 5, wherein the seed layer covers an overhang surface of the buffer layer.

7. The apparatus of claim 1, wherein the buffer layer covers a portion of a sidewall of the hole.

8. The apparatus of claim 1, wherein the substrate is a core of a package substrate.

9. The apparatus of claim 1, wherein the buffer layer is an organic buildup film.

10. The apparatus of claim 1, wherein the hole has an hourglass shaped cross-section.

11. An apparatus, comprising:
a glass core;
a buffer layer over and in direct contact with the glass core; and
a via through the glass core and the buffer layer, wherein the via comprises:
a first sidewall with a first slope through the buffer layer; and
a second sidewall with a second slope through at least a portion of the glass core, wherein the second slope is different than the first slope.

12. The apparatus of claim 11, wherein the via further comprises:
a step between the first sidewall and the second sidewall.

13. The apparatus of claim 11, further comprising:
a seed layer, wherein the seed layer is between the via and the glass core, and wherein the seed layer is between the via and the buffer layer.

14. The apparatus of claim 11, wherein the buffer layer comprises an organic buildup film.

15. The apparatus of claim 11, wherein a top surface of the via is coplanar with a top surface of the buffer layer.

16. The apparatus of claim 11, wherein a top surface of the via is recessed from a top surface of the buffer layer.

17. The apparatus of claim 11, further comprising:
buildup layers over the buffer layer.

18. An apparatus, comprising:
a board;
a package substrate coupled to the board, wherein the package substrate comprises:
a glass core;
a layer over the glass core; and
a via through the glass core and the layer, wherein the via is separated from the glass core and the layer by a seed layer; and
a die coupled to the package substrate.

19. The apparatus of claim 18, wherein the layer is an organic buildup film, and wherein the layer directly contacts the glass core.

20. The apparatus of claim 18, wherein the via has a stepped profile.
